(19) United States
(12) Patent Application Publication
(10) Pub. No.: US 2009/0086554 A1
(43) Pub. Date: Apr. 2, 2009

(54) System and Method for Operating a Semiconductor Memory

(76) Inventors: Christophe Chanussot, Anitbes (FR); Vincent Gouin, Mandelieu (FR)

Correspondence Address: SLATER & MATSIL LLP, 17950 PRESTON ROAD, SUITE 1000, DALLAS, TX, 75252, US

(21) Appl. No.: 11/864,109

(22) Filed: Sep. 28, 2007

(51) Int. Cl. G11C 5/14; G11C 7/04; G11C 8/00

(52) U.S. Cl. 365/189.09; 365/211; 365/230.06

(57) ABSTRACT

A method for operating a semiconductor memory cell is disclosed. A first voltage is applied to the memory cell. The first voltage is dependent on temperature and semiconductor process variation in a manner that keeps the memory cell in a stable region of operation.

### TECHNICAL FIELD

This invention relates generally to semiconductor devices and methods, and more particularly to devices and methods for operating semiconductor memories.

### BACKGROUND

Semiconductor devices are used in a large number of electronic devices, such as computers, cell phones and others. One of the goals of the semiconductor industry is to continue shrinking the size and increasing the speed of individual devices. As devices shrink in size, the supply voltage at which the devices operate decreases. One challenge is to ensure stable and reliable operation of semiconductor devices at low power supplies.

The reduction in supply voltage of semiconductor devices creates both a challenge and an opportunity for semiconductor circuit technology. The opportunity lies in the reduced power required to operate circuits at low power supply voltages since the power consumed by a circuit is proportional to the square of the supply voltage for a given current. More recently, some semiconductor manufacturers have been implanting dynamic voltage scaling, that is designing circuits which operate on multiple power supplies. With dynamic voltage scaling, circuits that require a higher power supply voltage, for example, high performance analog and RF devices, can be operated from a high power supply, and other circuits, such as digital logic, can be run at a lower supply voltage. By partitioning power supplies, it is possible to advantageously optimize power consumption.

In general, the lower voltage limit at which circuits can reliably operate is determined by memory components within a circuit, more specifically SRAM memory. The primary reason behind this is a consequence of the small sizes used in state of the art sub-micron CMOS processes. Each SRAM cell typically consists of a six transistor memory cell which includes a cross-coupled inverter latch and a pair of pass-gate transistors whose gates are coupled to a word line. As the power supply voltage is lowered, however, the cross-coupled inverter latch can become unstable, and the memory cell may no longer reliably maintain its state. The voltage at which the onset of this unstable state is manifested can vary according to temperature, global process variation, and local statistical process variation. Because SRAM cells are generally designed with minimum sized transistors, and because these SRAM cells can be replicated over a hundred million times, statistical variation in the thresholds and other characteristics of these SRAM transistor cells can adversely affect yields. Because of the sheer number of cells involved, in order to assure reliable operation, an SRAM cell preferably should be designed to operate over six standard deviations (6%) of statistical process variation. For example, a CMOS device in a typical 45 nm or 65 nm process may have a nominal threshold voltage of about 500 mV. The threshold of a particular device, however, may vary statistically −300 mV to +300 mV over 6σ. Such a wide variation of thresholds can place a particular memory cell at risk for instability or metastability. The onset of metastability for a cell with a high degree of statistical threshold variation in conditions typically occurs at a supply voltage of about 0.9 volts.

Various solutions have been proposed to alleviate the problem of instability in memory cells at low voltages. For example, some prior art solutions have asserted a reduced word line voltage in order to stabilize memory cells. Unfortunately, due to the wide range of temperatures at which RAM cells are required to operate, such a reduced word line voltage places the memory at risk of slow operation and reduced read/write margins.

In the field of small, densely packed applications using small geometry transistors, what is needed is a memory that can be read and operated at a low voltage in a stable manner, without losing its read/write margin at process corners and at temperatures where metastability is not an issue.

### SUMMARY OF THE INVENTION

In one embodiment of the present invention, a method for operating a semiconductor memory cell is provided. A first voltage is applied to the memory cell. The first voltage is dependent on temperature and semiconductor process variation in a manner that keeps the memory cell in a stable region of operation.

The foregoing has outlined rather broadly features of the present invention. Additional features of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a-1d illustrate schematics of preferred embodiment systems for operating a semiconductor memory;

FIGS. 2a and 2b illustrate schematics of alternative embodiment systems for operating a semiconductor memory; and

FIGS. 3a-3c illustrate timing diagrams of preferred and alternative embodiments of the present invention.

Corresponding numerals and symbols in different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of preferred embodiments are discussed in detail below. It should be appreciated, however, that the present invention provides many applicable inventive concepts that may be embodied in a wide variety of specific contexts. The specific embodiments discussed are merely illustrative of specific ways to make and use the invention, and do not limit the scope of the invention.

The invention will now be described with respect to preferred embodiments in a specific context, namely a system and method for operating a MOS SRAM. Concepts of the invention can also be applied, however, to other electronic devices, such as other types of memory, or other circuits with process and temperature dependent performance sensitivities.

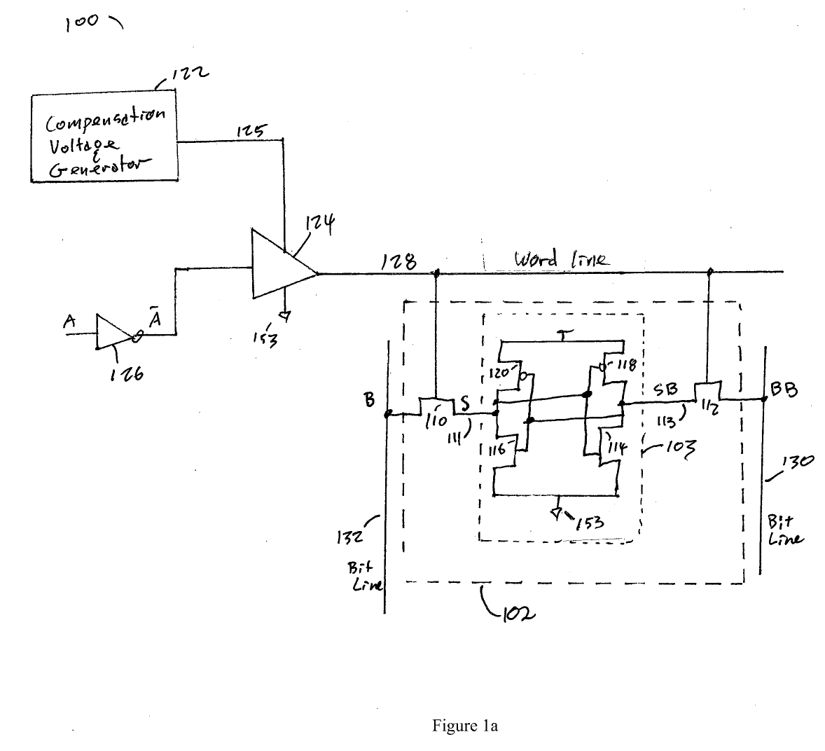

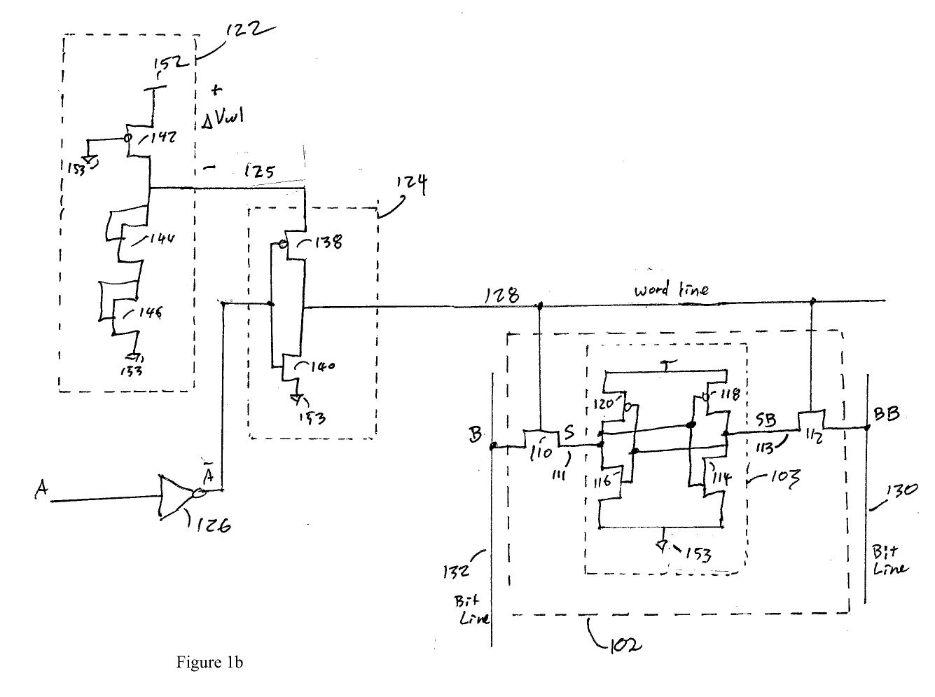

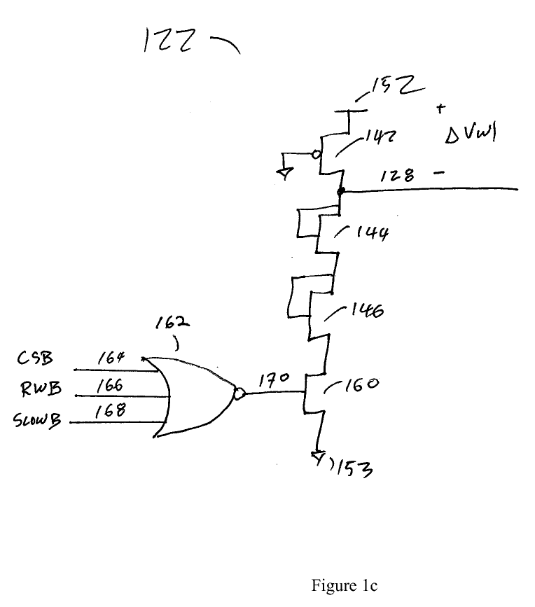

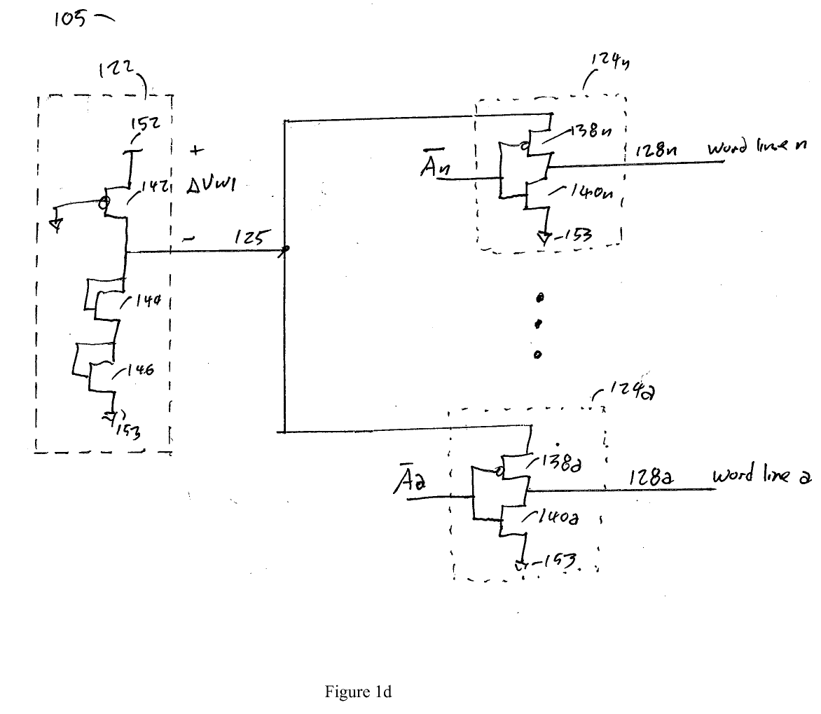

Referring first to FIG. 1a, an exemplary diagram of an SRAM memory 100 is shown. The memory comprises a six transistor SRAM memory cell 102. This six transistor memory cell 102 consists of a cross-coupled inverter latch 103. Ideally, the state of memory cell 102 is maintained in the absence of external stimuli by the cross-coupled inverter latch 103 when word line 128 is held low, and when NMOS pass transistors 110 and 112 are in a non-conductive state. When SRAM memory cell 102 undergoes a read operation, word line 128 is brought high, thereby turning on NMOS pass transistors 110 and 112. The state of cross-coupled inverter latch 103 is thereby asserted on bit lines BB 130 and B 132. Using cross-coupled inverter latch structures 103, bit lines 130 and 132 will generally be brought to opposite polarity. For example, when bit line BB 130 is brought high, bit line B 132 is brought low. In alternative embodiments of the present invention, other memory cell structures besides six transistor memory cell 102 may be used, for example, an eight transistor memory cell, or other memory cell structures.

In most semiconductor processes, device parameters are dependent on process variation and temperature. Process variations can occur on a global scale across a particular wafer, for example, resulting from a higher or lower than nominal doping concentration across an entire wafer lot as a result of a higher or lower than nominal process setting, or the process variation can be a result of device-to-device statistical variation, for example, channel length variation due to geometric variation. Commonly, global process variation will make a particular device “strong” or “weak” across the wafer in the case of PMOS and NMOS devices. Global process variation may effect the threshold voltage of these devices, for example, by variation in ion implant levels. For example, if a threshold voltage of a MOS device is high, the device is considered a weak device because of its reduced ability to sink current at a given gate-source voltage. Conversely, a global process variation with individual parameters that may culminate in a low threshold voltage for a MOS device would be considered a strong device because of its ability to sink a higher than nominal current for a given source-drain voltage.

In the case of a semiconductor memory, however, global process variations are not the only cause of process variations that result in strong devices and weak devices. Statistical process variations among devices, more particularly geometric variations across a physical dimension of a wafer, will result in threshold variations across the same wafer and across the same die or semiconductor memory unit. The problem of statistical process variation across a die or a particular semiconductor memory is serious because of the sheer number of semiconductor memory cells that may be present in a particular memory. For example, it is not uncommon to have a memory that may comprise tens of millions of semiconductor memory cells.

In 45 nm and 65 nm CMOS processes, a typical threshold voltage for a CMOS transistor used within a memory cell may be on the order of 500 mV. Device per device threshold variation however may have a standard deviation on the order of a few tens of millivolts; however, when millions of individual memory cells are taken into account, statistical variations of the thresholds in the memory cell may yield devices with thresholds varying on the order of −300 mV to +300 mV. For example, a typical enhancement mode NMOS device does not conduct source-drain current when the device's gate is grounded. In extreme process cases, however, when NMOS devices are fast (e.g., NMOS devices have a lower than nominal threshold), it is possible for a particular grounded-gate NMOS device with a high degree of statistical variation to conduct current.

Process and temperature variations can cause metastability issues in circuits that need to hold a particular state, for example in latches, flip-flops, or in this case, SRAM memory cells. A stable device will hold its state, whereas an unstable or metastable device may flip its state or create an output of an indeterminate state.

FIG. 1a can be used to illustrate how having fast NMOS devices, slow PMOS devices and high temperatures creates a condition were metastability problems are most likely to occur. When the memory is read, word line 128 is asserted high, NMOS pass transistors 110 and 112 are turned on, and bit lines B 132 and BB 130 are precharged to a logic high with respect to ground node 153. Assuming a low logic state is stored on node S 111 and a high logic state on node SB 113, certain V_{T} mismatch distributions in six transistor memory cell 102 can lead to unstable behavior of memory cell 102. An example of such a distribution is when NMOS pass transistor 110 is strong, NMOS device 116 is weak, PMOS device 120 is strong, and NMOS device 114 is strong. (In this case, NMOS pass transistor 110 would have a lower V_{T} than NMOS device 116 and therefore would be a stronger device). When NMOS pass transistor 110 turns on, the voltage on node S 111 begins to increase from its programmed low state because NMOS device 116 is too weak to quickly discharge high bit line at node B 132. As the voltage on node S 111 increases, the gate of strong NMOS device 114 will increase in voltage. As a result, node SB 113 will start to go low and turn on strong PMOS device 120. Once strong PMOS device 120 turns on, node S 111 will be pulled up to the supply and the state of memory cell 102 will have been flipped opposite its programmed state. This effect will typically occur when node S 111 raises above the threshold of the inverter formed by PMOS device 118 and NMOS device 114. This change in the state of memory cell 102 is undesirable from the perspective of any user of a semiconductor memory, as reliability of a semiconductor memory is critical.

In a preferred embodiment of the present invention the difficulties arising from process-induced memory cell metastability is alleviated by controlling the voltage on word line 128 in process conditions where it is likely that memory cell 102 will experience metastability or instability. FIG. 1a shows that word line 128 driven by word line driver 124. In this preferred embodiment of the present invention, power supply node 125 of word line driver 124 is provided a compensation voltage generator 122. In conventional embodiments, power supply node 125 of word line driver 124 is typically coupled to a global supply routed to an off-chip power supply. In this preferred embodiment, however, power supply node 125 of word line driver 124 is provided with a compensated voltage at power supply node 125, where the compensated voltage is typically below the voltage of power supply. Compensation voltage generator 122 provides a lower voltage in process regions where it is likely for memory cell 102 to experience metastability, and provides a higher voltage in process regions where memory cell 102 is less likely to experience metastability. Using a lower voltage to turn on NMOS pass transistors 110 and 112 creates a higher drain to source resistance. The drive of NMOS pass transistors 110 and 112 is then weaker, so under worst case mismatch conditions, node S 110 remains below the threshold of the inverter formed by PMOS device 118 and NMOS device 114 during the entire read operation. Memory cell 102, therefore, remains stable.

The input of inverter 126 is typically coupled to an address decoder (not shown). The output of inverter 126 is coupled to the input of word line driver 124. In a preferred embodiment of the present invention, word line driver 124 is implemented as an inverter. However in alternative embodiments of the present invention, word line driver 124 may be implemented by a circuit other than an inverter. Inverter 126, however, may not be present in other alternative embodiments of the present invention. It can further be seen that other configurations of driving the word line 128 is possible without detracting from the spirit of the invention as disclosed herein.

Turning to FIG. 1b, another preferred embodiment of the present invention is illustrated. FIG. 1b is similar to FIG. 1a, except that proposed physical embodiments are shown for word line driver 124 and compensation voltage generator 122. In a preferred embodiment of the present invention the word line 128 is driven by an inverter which includes PMOS transistor 138 and NMOS transistor 140. The source of PMOS transistor 138 is coupled to the output of compensation voltage generator 122. In a preferred embodiment of the present invention, compensation voltage generator 122 includes two diode-connected NMOS devices 144 and 146 coupled to ground 153 in series. The drain of NMOS device 144 is coupled to the drain of PMOS device 142 thus providing a current across diode-connected NMOS devices 144 and 146.

In preferred embodiments of the present invention, NMOS devices 144 and 146 are biased so that the voltage at node 125 has an inverse relationship with temperature; for example, as temperature increases, the voltage at node 125 decreases. One way to ensure that diode-connected transistors 144 and 146 have an inverse temperature relationship is to size these devices wide enough for this inverse temperature relationship to manifest. If devices 144 and 146 are too narrow for a given current, they may have a positive voltage versus temperature relationship. In this preferred embodiment of the present invention, the width of devices 144 and 146 is typically a few tens of microns to over a few hundred microns. By having a word line voltage that is proportional to the V_{T}, yet inversely proportional to temperature, the stability of memory cell 102 can be insured under the conditions at which stability is marginal. In conditions where stability is not impaired by process and temperature, for example in low temperature conditions or in conditions where NMOS devices have high thresholds, the word line voltage will experience a lower reduction with respect to the nominal supply voltage 152.

It can be seen that PMOS device 142 serves as a source of current for NMOS devices 144 and 146. In alternative embodiments of the present invention, PMOS device 142 can be replaced by other devices such as a resistor or a current source. Furthermore, in alternative embodiments of the present invention, diode-connected NMOS devices 144 and 146 may be replaced by either a single device or multiple devices connected in series. In other alternative embodiments of the present invention, compensation voltage generator 122 may be accomplished by other means such as a regulated voltage supply or any number of methods known in the art to generate a reference voltage proportional to V_{T}.

Tables 1 and 2 summarize the performance of the embodiment shown in FIG. 1b according to voltage ΔVw1, which is defined as the voltage difference between the voltage at supply node 152 and the asserted word line 128 voltage during a write operation. Table 1 illustrates that stability can be achieved across a commercial temperature range of between −40° C. and 125° C. for a nominal process. At −40° C., read/write margins are only slightly impacted. While stability at −40° C. could be achieved without a reduction in power supply, ΔVw1 for the preferred embodiment is only 6 mV, which is acceptably small. Table 2 illustrates that stability can be achieved across all global process variations at high temperature. High temperature is considered to cause the worst cases in terms of stability.

TABLE 1

| Temperature | | ΔVwl with |
|---|---|---|
| with Nominal | Necessary ΔVwl | 2 NMOS diodes |
| Process | for stability (mV) | (mV) |
| 125 | 48 | 53 |
| 27 | 20 | 20 |
| −40 | 0 | 6 |

TABLE 2

| Process at | Necessary ΔVwl | ΔVwl with 2 NMOS diodes |
|---|---|---|
| 125 C. | for stability (mV) | (mV) |
| Fast | 65 | 65 |
| Nominal | 48 | 53 |
| Slow | 30 | 43 |

In preferred embodiments of the present invention, having a compensation voltage generator 122 that produces a voltage proportional to V_{T} of an NMOS and/or a PMOS device may be entirely sufficient to provide reliable and stable memory access. In other embodiments, compensation voltage generator 122 may produce a voltage that is a function of V_{T} of a MOS device, a function of a V_{BE} of a BJT device, a junction potential of a diode, or a function of another process variable. In some embodiments, however, it may be desirable to select between a compensated voltage and an unregulated supply voltage.

In the preferred embodiment of the compensation voltage generator 122 shown FIG. 1c, the compensated voltage is selectable by placing an NMOS switch in series with diode-connected devices 144 and 146. In preferred embodiments of the present invention, the output of NOR gate 162 controls the conductive state of NMOS switch device 160. Signals such as CSB 164, RWB 166, and SLOWB 168 are used to control the state of NMOS switch device 160. Signal SLOWB 168 is an active low signal that is asserted when the memory operates at low voltage and high performance is not desired. Signal RWB 166 indicates that the memory is being used in a read mode, in which case it is desirable to activate the compensation voltage generator 122. Signal CSB 164 is an active low chip select signal that shuts off compensation voltage generator 122 when the chip or memory is not selected to be in operation. In modes where compensation voltage generator 122 is to provide a compensated voltage, node 170 is brought high thereby turning on NMOS device 160. In preferred embodiments of the present invention, word line 128 is driven by supply voltage 152 when compensation voltage generator 122 is not activated. Driving word line 128 with a higher voltage is advantageous while the memory is being written because writing a memory cell entails imposing the state of bit lines BB 130 and B 132 (FIG. 1b) onto memory cell 102 (FIG. 1b). Furthermore, in preferred embodiments of the present invention, the word line 128 is activated for a shorter duration of time in a write operation then for a read operation. The cell, therefore, has less time to flip. In alternative embodiments, however, word line 128 is activated for a longer duration of time in a write operation then for a read operation. Having a longer write time operation may occur in multi-array SRAM with segmented bit lines where the read operation is performed globally and the write operation is performed locally. Further, in some embodiments of the present invention it may be necessary to activate compensation voltage generator 122 only during a read operation, but in other embodiments, compensation voltage generator 122 may be operated during both a read and a write operation.

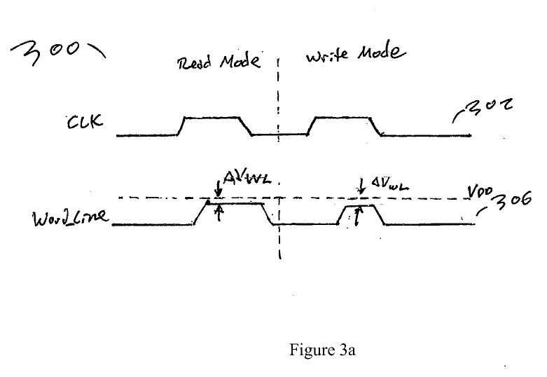

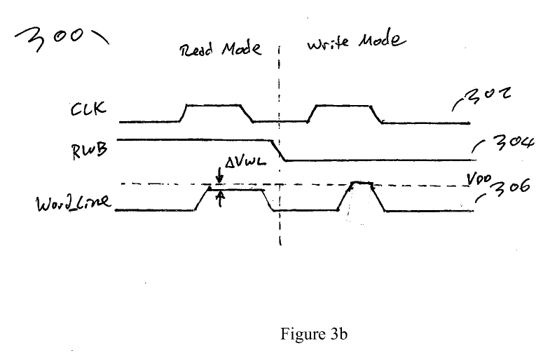

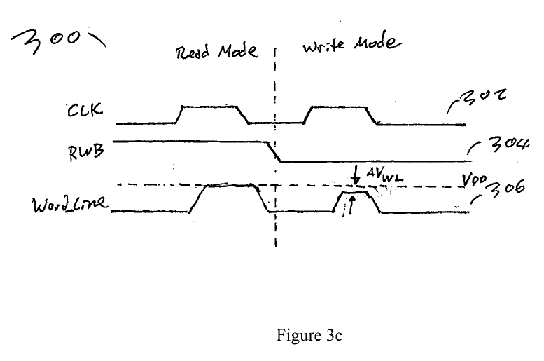

Turning to FIG. 3a, a timing diagram 300 of a preferred embodiment of the present invention is shown. CLK 302 represents a clock signal used to run the memory and word_line 306 represents the word line voltage. As can be seen, the pulse width on the word_line 306 is wider during a memory read than during a memory write. As discussed hereinabove, the shorter pulse width during a memory write helps ensure stability. In this preferred embodiment, word_line 306 is asserted to a voltage that is V_{DD}-ΔVw1, or ΔVw1 lower than the nominal power supply during both memory reads and memory writes. In alternative embodiments of the present invention, the pulse width of word_line 306 may be the same when the memory is being read and when the memory is being written.

FIG. 3b shows a timing diagram 300 of an alternative embodiment of the present invention. RWB 304 represents a read signal as shown in FIG. 1c. As can be seen, when RWB 304 is high, the memory is in a read mode, and word_line 306 is asserted to a voltage that is V_{DD}-ΔVw1, or ΔVw1 lower than the nominal power supply. When the memory is being written, however, word_line 306 is driven to the V_{DD} or the nominal power supply. In an alternative embodiment of the present invention shown in FIG. 3c, however, word_line 306 is driven to V_{DD}-ΔVw1 while the memory is being written, and driven to V_{DD} or the nominal power supply while the memory is being read.

Returning to FIG. 1c, it can be seen that other possibilities and strategies to control or activate compensation voltage generator 122 may be possible. For example, different logic combinations and different logic schemes may be used to determine whether compensation voltage generator 122 is activated, or to determine whether different switched topologies need to be used to select between a compensated voltage and the voltage at supply node 152. It should be noted that the embodiment shown in FIG. 1c is representative of many possible embodiments that can be used to effect control on compensation voltage generator 122.

Turning to FIG. 1d, another preferred embodiment of the present invention, memory system 105, is shown. As was mentioned hereinabove, it is desirable for NMOS devices 144 and 146 to be physically wide so that the output of compensation voltage generator 122 is inversely proportional to temperature. While it is possible to have every word line driver 124a-124n associated with its own reference voltage generator 122, integrated circuit real estate can more efficiently be allocated by allocating a single voltage generator 122 to be associated with a plurality of word line drivers 124a to 124n. Such a scheme as shown in FIG. 1d allows for NMOS devices 144 and 146 to be geometrically large without taking up too much area on the die. The number of word line drivers 124a-124n which can be paired with compensation voltage generator 122 is preferably between about thirty-two word line drivers 124 and sixty-four word line drivers 124. However, it should be noted that the optimal number of word line drivers 124 associated with a single reference voltage generator 122 is dependent on process, the required speed of the memory and the specifications of the memory to be designed, so fewer than thirty-two and greater than sixty-four word line drivers 124 may be coupled to a single compensation voltage generator 122 in alternative embodiments.

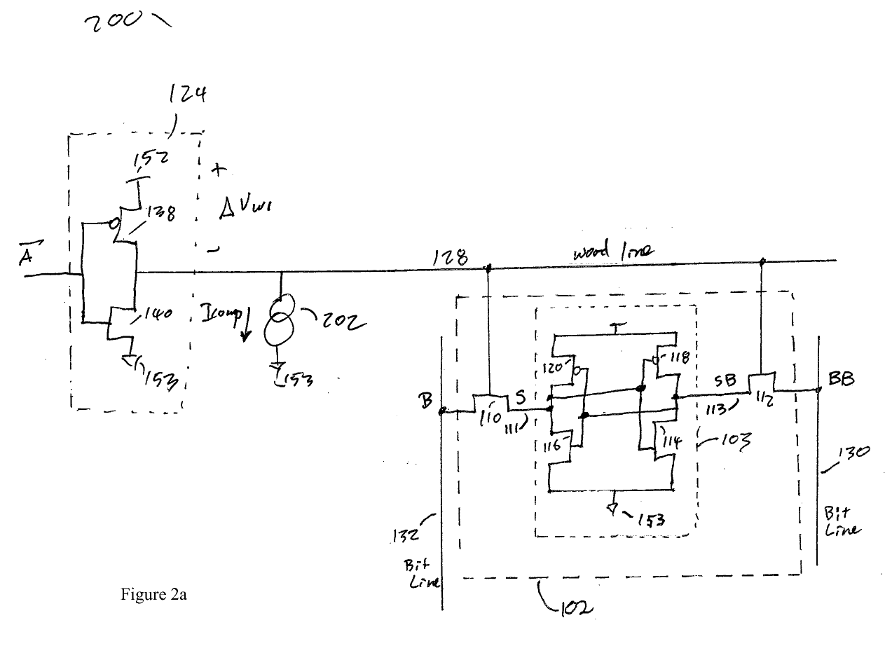

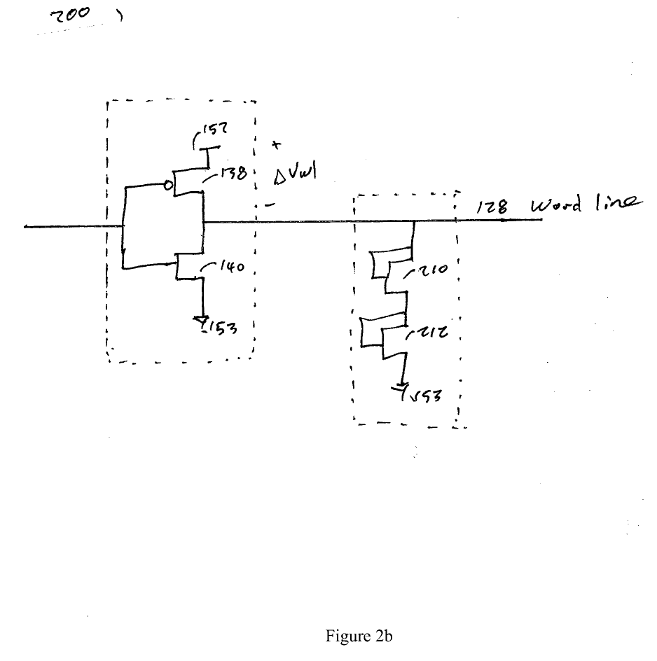

Turning to FIG. 2a, memory system 200, an alternative embodiment of the present invention is shown. This alternative embodiment is similar to the embodiments shown in FIGS. 1a-1d; however, instead of a compensation voltage generator reducing the asserted word line 128 voltage, a compensation current source 202 placed in shunt with the output of word line driver 122 is used to reduce the asserted voltage of word line 128. In preferred embodiments of the present invention, compensation current source 202 provides a current proportional to temperature and dependent on the process corner, so that the voltage drop between the source and drain of PMOS device 138 places memory cell 102 closer to an optimal region for stability. Current source 202 can be implemented in a number of ways known in the art, however, a specific example is shown in FIG. 2b.

FIG. 2b shows word line driver 124 with compensating current source 202 placed in shunt with its output. In this embodiment of the present invention, compensating current source 202 is implemented by two diode-connected NMOS transistors 210 and 212 coupled in series. Compensating current source 202 can be viewed either as a current source which sinks a temperature dependent current though PMOS device 138, or it can been treated as applying two threshold voltages derived from the series combination of NMOS devices 210 and 212. Either way, the structure illustrated in this embodiment affects the asserted voltage at word line 128 to compensate for the potential metastability of memory cell 102 (FIG. 1a).

The above described embodiments ensure stable operation of SRAM memory devices across process and temperature especially in situations where the multitude of memory cells require that the memory operates robustly over many standard deviations of statistical process variation. Additionally, embodiments of the present invention disclosed herein ensure that in slow conditions where metastability is unlikely, read and write margins can be adequately protected.

It will be understood by those skilled in the art that other alternative embodiments of the present invention are possible. For example, even though SRAM cells with NMOS access transistors have been disclosed, the concepts of this invention can be applied to memory cells with PMOS access transistors. It is also possible to apply concepts of the invention as described herein to other types of memories, for example, EEPROM or DRAM. The concepts of the invention can also be applied to other forms of logic, such as logic that utilizes static and dynamic memory elements, such as latches and or flip-flops.

It will also be readily understood by those skilled in the art that materials and methods may be varied while remaining within the scope of the present invention. It is also appreciated that the present invention provides many applicable inventive concepts other than the specific contexts used to illustrate preferred embodiments. Accordingly, the appended claims are intended to include within their scope such processes, machines, manufacture, compositions of matter, means, methods, or steps.

What is claimed is:

1. A method for operating a semiconductor memory cell, the method comprising applying a first voltage to the memory cell, wherein the first voltage comprises dependencies on semiconductor process variation and on temperature, and wherein the dependencies keep the memory cell in a stable region of operation.

2. The method of claim 1, wherein the applying the first voltage comprises
asserting the first voltage on a word line of the memory cell while the memory cell is being read; and
asserting the first voltage on the word line of the memory cell while the memory cell is being written.

3. The method of claim 2, wherein:
the asserting the first voltage on the word line of the memory cell while the memory cell is being read comprises asserting the first voltage on the word line for a first duration; and
the asserting the first voltage on the word line of the memory cell while the memory cell is being written comprises asserting the first voltage on the word line for a second duration, wherein the first duration is greater than the second duration.

4. The method of claim 2, wherein:
the asserting the first voltage on the word line of the memory cell while the memory cell is being read comprises asserting the first voltage on the word line for a first duration; and
the asserting the first voltage on the word line of the memory cell while the memory cell is being written comprises asserting the first voltage on the word line for a second duration, wherein the first duration is less than the second duration.

5. The method of claim 1, further comprising:
applying a second voltage to the memory cell, the second voltage being greater than or equal to the first voltage, wherein:
applying the second voltage comprises asserting the second voltage on a word line of the memory cell while the memory cell is being written; and
applying the first voltage comprises asserting the first voltage on the word line of the memory cell while the memory cell is being read.

6. The method of claim 4, wherein the second voltage comprises a supply voltage

7. The method of claim 1, further comprising:
applying a second voltage to the memory cell, the second voltage being greater than or equal to the first voltage, wherein:
applying the second voltage comprises asserting the second voltage on a word line of the memory cell while the memory cell is being read; and
applying the first voltage comprises asserting the first voltage on the word line of the memory cell while the memory cell is being written.

8. The method of claim 7, wherein the second voltage comprises a supply voltage.

9. The method of claim 1, wherein the first voltage is proportional to a MOS threshold voltage, a diode junction voltage, or a bipolar junction transistor base-emitter voltage.

10. The method of claim 9, wherein the first voltage is inversely proportional to temperature.

11. The method of claim 1, wherein the dependencies maintain stability margins in fast conditions, and wherein the dependencies maintain read/write margins in slow conditions, and wherein the fast conditions comprise low thresholds and high temperatures and the slow conditions comprise high thresholds and low temperatures.

12. The method of claim 1, wherein the memory cell comprises a six transistor memory cell.

13. A method of operating a semiconductor memory cell, the method comprising reading the memory cell, the reading comprising applying a compensated voltage to a word line of the memory cell, the compensated voltage being less than or equal to a reference voltage, wherein the compensated voltage is proportional to a MOS threshold voltage.

14. The method of claim 13, further comprising writing the memory cell, the writing comprising applying the compensated voltage to the word line of the memory cell.

15. The method of claim 13, wherein the applying the compensated voltage comprises driving the word line with a word line driver, the word line driver comprising:
a compensation voltage generator comprising a compensation voltage output; and
a driver circuit coupled to the compensation voltage output and the word line.

16. The method of claim 15, wherein:
the compensation voltage generator comprises at least one diode-connected MOS transistor and a current supply coupled to the at least one diode-connected MOS transistor;
the current supply and the at least one diode-connected MOS transistor are coupled to the compensation voltage output; and
the at least one diode-connected MOS transistor comprises a MOS transistor comprising a gate and a drain, wherein the gate is electrically coupled to the drain.

17. The method of claim 16, wherein the at least one diode-connected MOS transistor comprises a plurality of MOS transistors coupled in series.

18. The method of claim 16, wherein the current supply comprises a transistor.

19. The method of claim 16, wherein the at least one diode-connected MOS transistor comprises an NMOS transistor and the current supply comprises a PMOS transistor.

20. A memory system comprising:
a memory cell coupled to a word line;
a voltage reference comprising at least one diode-connected MOS transistor, the at least one diode-connected MOS transistor comprising a gate and a drain, wherein the gate is electrically coupled to the drain; and
a word line driver coupled to the voltage reference, the word line driver comprising an output coupled to the word line.

21. The system of claim 20, wherein the at least one diode-connected MOS transistor comprises a plurality of diode-connected MOS transistors coupled in series.

22. The system of claim 20, wherein the voltage reference is coupled to a supply reference of the word line driver.

23. The system of claim 22, wherein the word line driver comprises a MOS transistor coupled between the voltage reference and the word line.

24. The system of claim 20, wherein the voltage reference further comprises a current source coupled to the at least one diode-connected MOS transistor.

25. The system of claim 24, wherein the current source comprises a MOS transistor.

26. The system of claim 20, further comprising a plurality of memory cells and a plurality of word line drivers, wherein a single voltage reference is coupled to supply references of the plurality of word line drivers.

27. The system of claim 20, wherein the voltage reference comprises a MOS switch coupled in series with the at least one diode-connected MOS transistor.

28. The system of claim 20, wherein the voltage reference is coupled to the output of the word line driver.
